(19) United States
(12) Patent Application Publication
(10) Pub. No.: US 2006/0279319 A1
(43) Pub. Date: Dec. 14, 2006

(54) Electronic component test system

(75) Inventors: Tai-Fu Pan, Chubei City (TW); Yin-hsuan Lai, Bausun Hsiang (TW); Jeng Yuan Lai, Taichung City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Siliconware Precision Industries Co., Ltd.

(21) Appl. No.: 11/451,056

(22) Filed: Jun. 12, 2006

(30) Foreign Application Priority Data
Jun. 14, 2005 (TW) 094119706

(51) Int. Cl. G01R 31/26

(52) U.S. Cl. 324/765

(57) ABSTRACT

A system for testing a die (or chip) of a semiconductor wafer is disclosed. It features measuring the temperature of the die according to a light beam radiated from the die. The temperature so measured functions as part of test record and/or the basis for controlling the temperature of the die. Measuring the temperature of a die in such a way will replace measuring the temperature of a die conventionally via the wafer carrier on which the die being tested is placed. The system comprises: a die test device for testing the performance and/or quality of a die; and a temperature detector separated from the die and the wafer, for measuring the temperature of the die according to a light beam radiated from the die. The temperature detector may be either connected to or embedded in the die test device, or be placed at another location. Another feature is the use of a light emitter which produces light beams directed to the die or the wafer for providing heat thereto. The application of the system can be extended to the other electronic components.

### FIELD OF THE INVENTION

The present invention relates to a system for testing electronic component such as IC semiconductor, particularly to a system for testing at least a die of a wafer, and specifically to a system measuring the temperature of a component based on a light beam radiated from the component being tested.

### BACKGROUND OF THE INVENTION

Testing of a wafer usually requires a temperature control system, which is represented by a conventional one illustrated by referring to FIGS. 1 and 2. The upper part of FIG. 1 shows a top view of it, and the lower part of FIG. 1 shows a side view of it. In FIG. 1, a wafer 1 is placed on a carrier 3, wherein wafer 1 includes a plurality of dice 2. FIG. 2 represents a temperature control system for a conventional process of testing a wafer. In FIG. 2, temperature detector 5 measures the temperature of carrier 3 on which wafer 1 (as shown in FIG. 1) is placed. Carrier temperature controller 10, in response to the temperature of carrier 3 measured by temperature detector 5, controls heater 4 to apply heat to carrier 3. On the other hand, cooling controller 11 controls cooling device 6 according to the temperatures of carrier 3 and cooling device 6. Cooling device 6 cools carrier 3 through in-flow circuit 7 and out-flow circuit 9.

As can be seen from FIGS. 1 and 2, if the temperature of carrier 3 measured by temperature detector 5 cannot accurately reflect the temperature of a die being tested (such as die 2 in FIG. 1 if it is being selected for test), there is no way for carrier temperature controller 10 and cooling controller 11 to let the temperature of the die (being tested) in a specified range, leading to a test result with serious errors or deviations. It can be seen from the aforementioned fact that a conventional system for testing a wafer cannot keep pace with the condition of requiring higher accuracy. This is because wafer 1 contacts carrier 3, and the die being tested contacts the other dice of wafer 1, both wafer 1 and carrier 3 act as huge media for dissipating the heat resulting from the test voltage and current applied to the die being tested, temperature detector 5 which contacts carrier 3 to measure the temperature of the die being tested surely cannot accurately detect the temperature of the die being tested.

FIGS. 3a and 3b are to show the fact that the actual temperature of a die being tested according to a conventional system cannot be measured. In FIG. 3a, a wafer (placed on a supporting surface of a carrier not shown in FIG. 3, but shown as carrier 3 in FIG. 1) has a diameter of 12 inches, a heat source of temperature 75° C. and size 12×12 mm is placed at a location 62 which is 122.5 mm away from the center 61 of wafer 1. Temperatures are measured at eight points A, B, C, D, E, F, G, H all located 140 mm away from center 61 of wafer 1 but separated from each other by an angle of 45 degrees. Temperatures are also measured at eight points a, b, c, d, e, f, g, h all located 105 mm away from center 61 of wafer 1 but separated from each other by an angle of 45 degrees. All the measured temperatures are depicted in FIG. 3b. In FIG. 3b, the values of temperature distributed along horizontal direction from left to right respectively represent the temperatures measured at points A, a, B, b, C, c, D, d, E, e, f, G. g, H, h. It can be seen from FIG. 3b that the temperatures measured at points A and a which are both distanced from heat source 62 of 75° C. by 17.5 mm, are lower than 25.4° C., and the temperatures measured at points B, b, C, c, D, d, E, e, F, f, G, g, H, h which are all distanced from heat source 62 of 75° C. by more than 17.5 mm, are lower than 25.1° C. The temperatures measured at all of these points are significantly lower than heat source of 75° C. Obviously the heat dissipation of carrier 3 and wafer 1 significantly affect the measurement of actual temperature of the die being tested, resulting in impracticality of the temperature control of the die being tested, leading to impossibility of accurate wafer test, or even putting wafer test far beyond specified temperature range.

To resolve the problem inherent in conventional systems of testing a wafer, the present invention is developed to provide an art wherein the temperature of a die of a wafer being tested is measured according to a light beam radiated directly from the die being tested rather than the heat conducted via a medium from the die being tested. The art provided by the present invention thereby immunizes the test of a die of a wafer against suffering the effect of heat dissipation of the wafer and the carrier supporting the wafer, significantly raising the reliability and accuracy of the test of a wafer. According to a lot of arts in related field, such as U.S. Pat. Nos. 5,198,752, 6,605,955, 6,288,561, 6,802,368, 6,771,086, temperature of a die being tested is measured indirectly, therefore these arts are inevitably subjected to the weakness of conventional systems of testing a die of a wafer.

### SUMMARY OF THE INVENTION

An object of the present invention is to provide a solution for directly measuring the temperature of a die of a wafer being tested.

Another object of the present invention is to provide a solution for measuring the actual temperature of a die of a wafer being tested, wherein the measured temperature constitutes part of a test record.

A further object of the present invention is to provide a solution for directly measuring the temperature of a die of a wafer being tested, wherein the measured temperature serves as a base to control the temperature of the die being tested.

Another further object of the present invention is to simplify the temperature control system for testing a wafer.

An even further object of the present invention is to upgrade the validity of temperature control of a die being tested.

Another even further object of the present invention is to upgrade the reliability and accuracy of testing a wafer.

An aspect of the present invention is a system for testing at least a die of a wafer. The system comprises: a carrier such as a plate for supporting the wafer; a die tester for testing the performance (including function) and/or the quality of the die; and a temperature detector separated from the die by a space, the temperature detector for measuring the temperature of the die according to a light beam radiated from the die. According to the present invention, the carrier may be made of metal or another material, the die tester includes a die-contactor for contacting the die to apply voltage/current to the die, and/or to conduct voltage/current out of the die. The measured temperature according to the present invention serves as part of a test record and/or as a base for controlling the temperature of the die being tested.

According to the present invention, the light beam received by the temperature detector for measuring the temperature of the die being tested is an infrared-ray radiated from the die being tested if the temperature detector is an infrared-ray temperature detector.

According to the present invention, as long as there is a light propagation path between the die being tested and the temperature detector, the temperature detector and the die being tested may be located at the same side or opposite sides relative to the carrier. For an example, if the temperature detector and the die being tested are located at the same side relative to the carrier, and there is a space between the temperature detector and at least part of the die being tested, the space constitutes a light propagation path for the light beam to propagate to the temperature detector from the die being tested. For another example, if the temperature detector and the die being tested are located at opposite sides relative to the carrier, the carrier must include at least one part of transparent portion between the temperature detector and the die being tested, so that the part of transparent portion constitutes part or all of the light propagation path for the light beam radiated from the die being tested to propagate therethrough to reach the temperature detector.

The system according to the present invention is preferably configured in such a way that a temperature compensator is included therein, and the temperature detector provides a temperature indicating signal corresponding to the measured temperature of the die being tested, (i.e., corresponding to the temperature measured according to the light beam radiated from the die being tested), and the die tester provides a test status indicating signal to indicate whether or not a test has been applied to a die, and the temperature compensator applies heat to the die according to the temperature indicating signal and test status indicating signal.

According to the present invention, if the temperature detector and the die being tested are at the same side relative to the carrier, and there is a propagation path between the temperature detector and the at least part of the die being tested, the location of the temperature detector is not limited, i.e., the temperature detector may be connected with or attached to the die tester, or the temperature detector may be embedded in the die tester, or the temperature detector is located anywhere at the same side (relative to the carrier) as the die being tested.

If the temperature detector is embedded in the die tester, the system constitutes another aspect of the present invention for testing at least a die of a wafer, and may be configured to comprise: a carrier for supporting the wafer; a testing apparatus including a temperature detector and a semiconductor tester such as a die tester which is for testing the performance (including function) and/or quality of a die and includes a contact-end for touching the semiconductor; and a light propagation path between the contact-end and the temperature detector, wherein the size of the light propagation path is such that at least part of the die being tested radiate a light beam to propagate through the light propagation path to be received by the temperature detector, thereby the temperature of the die being tested is measured by the temperature detector according to the light beam received from the die being tested. For example, the light propagation path is a space having a size meeting a path specification so that the temperature detector can receive, through at least part of the space, a light beam radiated from part or all of the die being tested, thereby the temperature of the die being tested is measured by the temperature detector.

The semiconductor tester preferably comprises a main body, a protruding portion such as a pin or a needle, and the contact-end, with the protruding portion between the main body and the contact-end. If the light propagation path meets such a condition that the contact-end is between the protruding portion and part of the light propagation path, the die being tested will certainly have at least part thereof connecting the light propagation path, and the light beam radiated from the die being tested can propagate through the light propagation path to the temperature detector.

According to the present invention, the semiconductor tester may be configured to contain or provide a quality test record after testing a semiconductor, and the temperature detector may be configured to receive a light beam radiated from the die being tested, and to contain or provide a temperature measuring value corresponding to (or according to) the received light beam, and the testing apparatus is configured to provide a test result according to the quality test record and the temperature measuring value. According to the present invention, the semiconductor tester may also be configured to contain or provide a performance test record after testing a semiconductor, and the testing apparatus is configured to provide a test result according to the performance test record and the temperature measuring value. Furthermore, the temperature detector may be configured to provide a temperature compensation signal for initiating a temperature controller when the temperature measuring value is beyond a specified temperature range.

The application of the system according to the present invention is not limited to the test of a semiconductor. Instead, the application of the system according to the present invention can be extended to any electronic component such as semiconductor component or component including an Integrated Circuit. The system for such an application comprises: a testing apparatus for testing at least one of the features of a electronic component, a temperature detector for measuring the temperature of the electronic component according to a light beam radiated from the electronic component, and a light propagation path between the contact-end and the temperature detector, wherein the features of the electronic component includes the performance and the quality of the electronic component, the temperature detector is separated from the electronic component by a space, the testing apparatus has a contact-end for touching the electronic component, and the size of the light propagation path meets a path specification which is such that the electronic component has at least part thereof contacting the light propagation path and radiating a light beam to propagate through part or all of the light propagation path to reach the temperature detector. The system preferably further comprises a carrier for supporting the electronic component. In fact, the system according to the present invention is not limited to a specific type of component. As long as a component can radiate a light beam characterizing or representing the temperature of itself, i.e., as long as a light beam radiated from a component can be used to measure the temperature of the component, the system according to the present invention can be applied to the component.

Because the indirect temperature measurement of a die in conventional systems of testing a wafer is replaced by direct temperature measurement of a component, the system according to the present invention is capable of simplifying temperature control system, improving the validity of temperature control, thereby upgrading the reliability and accuracy of testing a wafer.

### BRIEF DESCRIPTION OF THE DRAWINGS

FIGS. 1, 2, 3a, and 3b show conventional arts and facts related thereto.

FIG. 4a shows a first embodiment of testing a wafer according to the present invention.

FIG. 4b shows an embodiment of applying heat to a die in a system of testing a wafer according to the present invention.

FIG. 5 shows a second embodiment of testing a wafer according to the present invention.

FIG. 6 shows a third embodiment of testing a wafer according to the present invention.

FIG. 7 shows a fourth embodiment of testing a wafer according to the present invention.

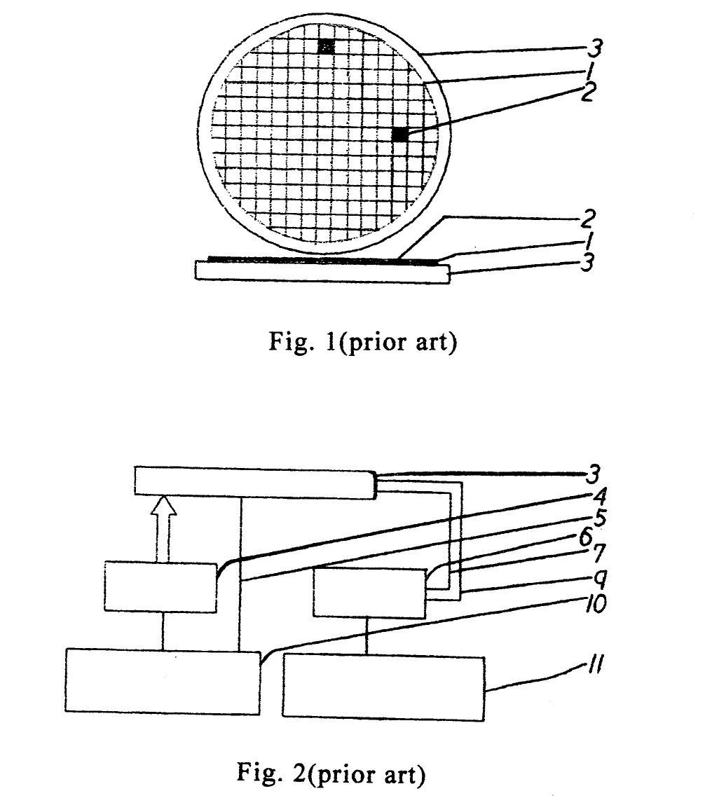

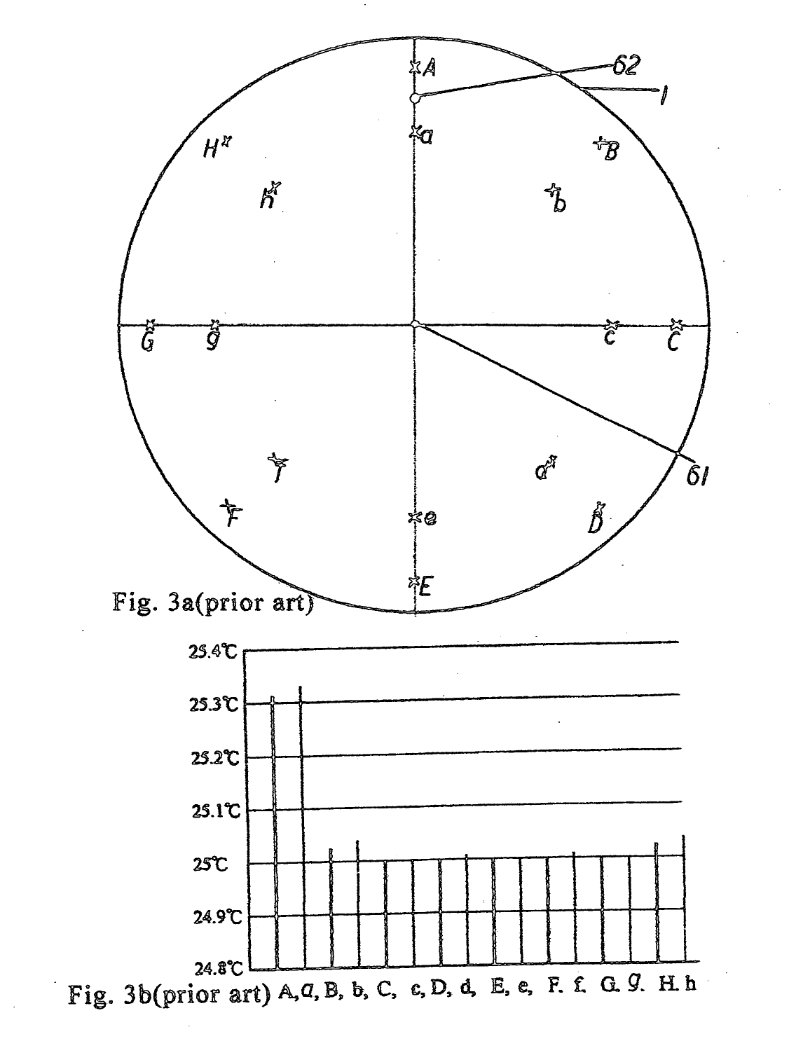

### DETAILED DESCRIPTION OF THE PREFERRED EMBODIMENTS

For convenient illustration, the size ratio of each component to another component according to the drawings does not necessarily correspond to what is practically used.

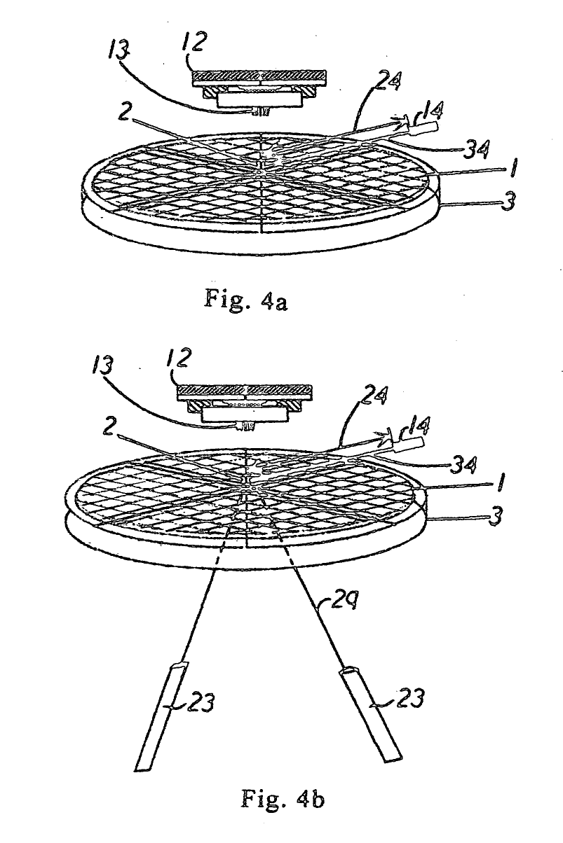

FIG. 4a shows a first embodiment of a system for testing at least a die 2 of a wafer 1. The system comprises: a carrier 3 for supporting the wafer 1; a die tester 12 for testing the performance (including function) and/or the quality of the die 2; and a temperature detector 14 separated from the die 2 by a distance 24 (such as the length of a space), wherein the temperature detector 14 is for measuring the temperature of the die 2 according to a light beam (not shown in the figure) radiated from the die 2.

According to FIG. 4a, if there is a space (the space is not marked in the figure because it can be easily understood) in the shape of a straight cylinder between temperature detector 14 and part of die 2, with the length of the straight cylinder corresponding to the distance 24, the space in the shape of the straight cylinder can constitute a light propagation path 34 which allows the light beam radiated from die 2 to propagate therethrough to reach temperature detector 14. Although the light propagation path 34 shown in FIG. 4a is a space in the shape of a straight cylinder, the light propagation path for a light beam to propagate to a temperature detector from a die according to the present invention is neither limited to a space, nor limited to the shape of a straight cylinder. As long as a light propagation path allows the light beam radiated from die 2 to propagate to a temperature detector 14 where the temperature of die 2 can be measured according to the received light beam, the light propagation path may be anything such as a space, a transparent object, a straight optical fiber, a curved optical fiber, etc.

FIG. 4b shows an embodiment of applying heat to a die 2 in a system of testing a wafer 1 according to the present invention, wherein wafer 1 is supported by a carrier 3. Light emitter 23 (such as an electric bulb, an electric lamp, etc) is used to provide heat in such a way that the temperature of wafer 1 or die 2 is raised.

The light beam 29 provided by light emitter 23 is directed to wafer 1 or die 2. Although light beam 29 in FIG. 4b may be deemed to pass through carrier 3, the light beam to be applied to die 2 for heating die 2 according to the present invention can propagate directly to a die being tested from many feasible directions without need of passing through carrier 3. Light emitter 23 and temperature detector 14 according to the present invention may be integrated to control the temperature of the die being tested. For example, temperature detector 14 may be configured to receive the light beam radiated from the die being tested, and to contain or provide a temperature measuring value corresponding to (or according to) the received light beam, and to provide a temperature compensation signal when (or if) the temperature measuring value is beyond a specified temperature range, wherein the temperature compensation signal is for initiating a temperature controller to control the heat output of light emitter 23, and the specified temperature range is the temperature range good for the die being tested or fitting the condition of testing a die.

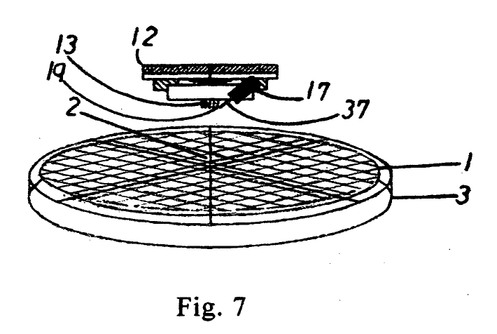

The system for testing a die of a wafer according to the present invention preferably further comprises a driver (not shown in the FIG. because it is easily understood) for driving carrier 3 in such a way that the die 2 reaches a test location (not shown in the figure because it is also easily understood) which corresponds to a contact-end (not shown in the figure because it is also easily understood) of die-contactor 13, thereby die 2 is ready to be touched by the contact-end (corresponding to the contact-end 19 in FIGS. 6 and 7) of die-contactor 13.

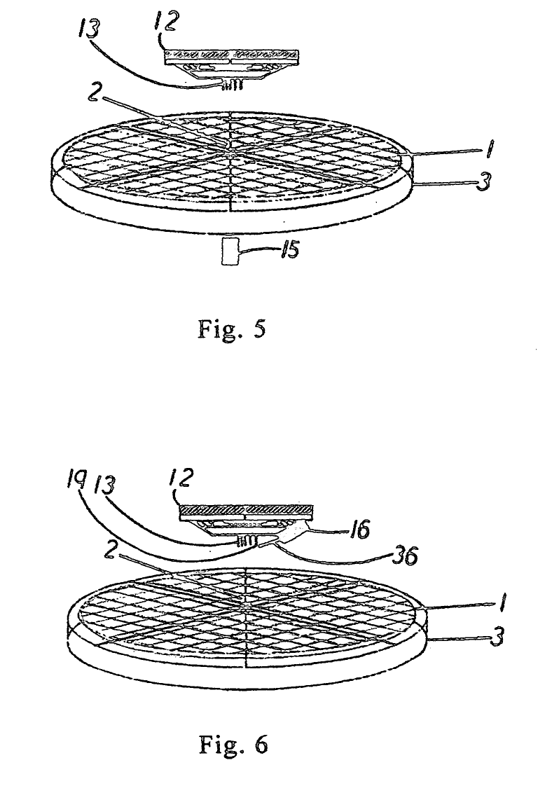

FIG. 5 shows a second embodiment of a system of testing at least a die 2 of a wafer according to the present invention. The system comprises a carrier 3, a die tester 12, and a temperature detector 15, wherein carrier 3 is for supporting wafer 1 and includes at least one transparent portion (not shown in the figure) between die 2 and temperature detector 15, the transparent portion is for a light beam (not shown in the figure) radiated from die 2 to pass therethrough to be received by temperature detector 15, and temperature detector 15 measures the temperature of die 2 according to the received light beam. According to the second embodiment, die tester 12 is for testing the performance and/or the quality of at least a die 2 of wafer 1, and die tester 12 includes a die-contactor 13 for contacting die 2 (the die being tested), and the transparent portion of carrier 3 or all of carrier 3 may be made of quartz. The temperature detector 15 according to the second embodiment does not necessarily contact carrier 3 because a space between temperature detector 15 and carrier 3 may also constitute part of a light propagation path.

FIG. 6 shows a third embodiment of testing a die 2 of a wafer 1 according to the present invention. The third embodiment according to FIG. 6 differs from the first embodiment (FIG. 4a) in that the temperature detector 16 according to FIG. 6 is connected with or attached to die tester 12 while the temperature detector 15 according to FIG. 4a is separated from die tester 12. Die-contactor 13 has at least a contact-end 19 for touching die 2, and there is a light propagation path 36 between contact-end 19 and temperature detector 16. When testing a die (such as die 2 in FIG. 6), contact-end 19 of die-contactor 13 touches die 2, light propagation path 36 allows the light beam radiated form die 2 to propagate therethrough to reach temperature detector 16. Preferably the size of light propagation path 36 is such that the light propagation path 36 connects at least part of die 2 when contact-end 19 of die-contactor 13 touches die 2.

FIG. 7 shows a fourth embodiment of testing a die 2 of a wafer 1 according to the present invention. The fourth embodiment (FIG. 7) differs from the third embodiment (FIG. 6) in that the temperature detector 17 according to FIG. 7 is embedded in die tester 12 while the temperature detector 16 according to FIG. 6 is connected or attached to die tester 12. In FIG. 7, there is a light propagation path 37 between temperature detector 17 and the contact-end. 19 of die-contactor 13. When testing a die (such as die 2 in FIG. 7), contact-end 19 of die-contactor 13 touches the die being tested (such as die 2 in FIG. 7), light propagation path allows the light beam radiated from die 2 to propagate therethrough to reach temperature detector 17. The entire light propagation path 37 may be outside of die tester 12, or part of light propagation path 37 is inside die tester 12 while another part of light propagation path 37 is outside of die tester 12. The location of light propagation path 37 is irrelevant as long as the light beam radiated from die 2 can be received by temperature detector 17 through light propagation path 37, and the temperature of die 2 can be measured according to the received light beam.

The die tester 12 according to FIGS. 6 and 7 can be deemed to be composed of a main body, a protruding portion such as die-contactor 13, and an end point such as contact-end 19 of die-contactor 13, with the protruding portion between the main body and the end point, i.e., with the main body and the end point respectively at the opposite sides of the protruding portion, thereby the die being tested will certainly have at least part thereof connecting the light propagation path 36 (or 37) as long as the end point is between the protruding portion and part of the fight propagation path when the end point touches the die being tested, whereby at least part of the light beam radiated from the die being tested can propagate through the light propagation path to be received by temperature detector 16 (or 17).

While the invention has been described in terms of what are presently considered to be the most practical or preferred embodiments, it shall be understood that the invention is not limited to the disclosed embodiment. On the contrary, any modifications or similar arrangements shall be deemed covered by the spirit of the present invention.

What is claimed is:

1. A system for testing at least a die of a wafer, comprising:
a carrier for supporting said wafer;
a die tester including a die-contactor, said die tester for testing at least one of the features of said die, the features of said die including the performance and the quality of said die, said die-contactor for contacting said die; and
a temperature detector separated from said die by a space, said temperature detector for measuring the temperature of said die according to a light beam radiated from said die.

2. The system according to claim 1 wherein said temperature detector is an infrared-ray temperature detector for measuring the temperature of said die according to a light beam of infrared-ray radiated from said die.

3. The system according to claim 1 wherein said carrier includes at least a transparent portion between said die and said temperature detector, said transparent portion for said light beam to propagate to said temperature detector.

4. The system according to claim 1 wherein said die tester and said temperature detector are separated by a space.

5. The system according to claim 1 wherein said die tester and said temperature detector are connected together, and said die-contactor has a contact-end for touching said die.

6. The system according to claim 5 further comprising a light propagation path between said contact-end and said temperature detector, said light propagation path for said light beam to propagate to said temperature detector from said die when said contact-end touches said die.

7. The system according to claim 6 wherein said light propagation path is a space.

8. The system according to claim 1 wherein said temperature detector is embedded in said die tester, and said die-contactor has a contact-end for touching said die.

9. The system according to claim 8 further comprising a light propagation path between said contact-end and said temperature detector, said light propagation path for said light beam to propagate to said temperature detector from said die when said contact-end touches said die.

10. The system according to claim 9 wherein said light propagation path is a space.

11. The system according to claim 1 further comprising a driver for driving said carrier in such a way that said die reaches a location corresponding to the location of said die-contactor.

12. The system according to claim 1 further comprising a light emitter for providing light in such a way that the temperature of said die increases.

13. The system according to claim 12 wherein said carrier is transparent, and the light provided by said light emitter reaches said wafer via said carrier to apply heat to said wafer.

14. The system according to claim 1 further comprising a temperature compensator, and wherein said temperature detector provides a temperature indicating signal, said die tester provides a test status indicating signal, and said temperature compensator applies heat to said die according to said temperature indicating signal and test status indicating signal.

15. A system for testing a semiconductor, comprising:
a carrier for supporting said semiconductor;
a testing apparatus including a semiconductor tester and a temperature detector, said semiconductor tester having a contact-end for touching said semiconductor, said temperature detector for measuring the temperature of said semiconductor according to a light beam radiated from said semiconductor; and
a light propagation path for said light beam to propagate to said temperature detector when said contact-end touches said semiconductor.

16. The system according to claim 15 wherein said semiconductor tester provides a quality test record after testing a semiconductor, said temperature detector provides a temperature measuring value according to said light beam when said semiconductor is tested by said semiconductor tester, and said testing apparatus provides a test result according to said quality test record and said temperature measuring value.

17. The system according to claim 15 wherein said semiconductor tester provides a performance measuring record after testing a semiconductor, said temperature detector provides a temperature measuring value according to said light beam when said semiconductor is tested by said semiconductor tester, and said testing apparatus provides a test result according to said performance test record and said temperature measuring value.

18. The system according to claim 15 wherein said temperature detector contains a temperature measuring value corresponding to said light beam when said semiconductor is tested by said semiconductor tester, and said temperature detector provides a temperature compensation signal if said temperature measuring value is beyond a temperature range.

19. A system for testing an electronic component, comprising:
a testing apparatus for testing at least one of the features of said electronic component, the features of said electronic component including the performance and the quality of said electronic component, said testing apparatus having a contact-end for touching said electronic component;
a temperature detector for measuring the temperature of said electronic component according to a light beam radiated from said electronic component; and
a light propagation path between said contact-end and said temperature detector, the size of said light propagation path meeting a path specification.

20. The system according to claim 19 further comprising a carrier for supporting said electronic component.
